(19) United States
(12) Patent Application Publication
(10) Pub. No.: US 2023/0363142 A1
(43) Pub. Date: Nov. 9, 2023

(54) SEMICONDUCTOR MEMORY DEVICE

(71) Applicant: Samsung Electronics Co., Ltd., Suwon-si (KR)

(72) Inventors: Intak Jeon, Suwon-si (KR); Hanjin Lim, Suwon-si (KR); Hyungsuk Jung, Suwon-si (KR)

(21) Appl. No.: 18/130,769

(22) Filed: Apr. 4, 2023

(30) Foreign Application Priority Data
May 3, 2022 (KR) 10-2022-0055029

(51) Int. Cl. H10B 12/00

(52) U.S. Cl. CPC H10B 12/31; H10B 12/033

(57) ABSTRACT

A semiconductor memory device includes an interlayer insulating layer, a plurality of first contact pads embedded in the interlayer insulating layer, a plurality of first work function adjustment patterns embedded in the interlayer insulating layer and disposed on the plurality of first contact pads, and a plurality of lower electrodes disposed on the plurality of first work function adjustment patterns.

### CROSS-REFERENCE TO RELATED APPLICATION(S)

This application is based on and claims priority under 35 U.S.C. § 119 to Korean Patent Application No. 10-2022-0055029, filed on May 3, 2022, in the Korean Intellectual Property Office, the disclosure of which is incorporated by reference herein in its entirety.

### BACKGROUND

This disclosure relates to a semiconductor memory device.

Recently, the high integration of memory products has accelerated owing to the rapid development of miniaturized semiconductor process technology, and therefore, a unit cell area is greatly reduced, and the operating voltage of semiconductor memory devices is lowered. For example, in a semiconductor memory device, such as dynamic random access memory (DRAM) and NAND flash memory, an area occupied by a unit memory cell corresponding to 1 bit decreases, which causes new defect factors and quality degradation factors.

### SUMMARY

Disclosed embodiments provide a semiconductor memory device having improved reliability.

According to an aspect of disclosure, a semiconductor memory device includes a substrate, an interlayer insulating layer formed on the substrate, a plurality of first contact pads embedded in the interlayer insulating layer, a plurality of first work function adjustment patterns embedded in the interlayer insulating layer and disposed on the plurality of first contact pads, the plurality of first work function adjustment patterns configured to adjust a work function of structures that include the plurality of first contact pads, a plurality of lower electrodes disposed on the plurality of first work function adjustment patterns and extending in a first direction perpendicular to a top surface of the substrate, an upper electrode covering the plurality of lower electrodes, and a dielectric layer disposed between the upper electrode and the plurality of lower electrodes.

According to another aspect of the disclosure a semiconductor memory device includes an interlayer insulating layer, a plurality of contact pads embedded in the interlayer insulating layer, a plurality of first lower electrodes disposed on the plurality of contact pads and extending in a first direction, a plurality of work function adjustment patterns embedded in the plurality of first lower electrodes, an upper electrode covering the plurality of first lower electrodes, and a dielectric layer disposed between the upper electrode and the plurality of first lower electrodes.

According to another aspect of the disclosure a semiconductor memory device includes an interlayer insulating layer, a contact pad embedded in the interlayer insulating layer, a work function adjustment cluster embedded in the contact pad, a lower electrode on the contact pad, a dielectric layer on the lower electrode, and an upper electrode on the dielectric layer.

### BRIEF DESCRIPTION OF THE DRAWINGS

Embodiments of the inventive concept will be more clearly understood from the following detailed description taken in conjunction with the accompanying drawings in which:

FIG. 1A is a diagram illustrating a semiconductor memory device according to some embodiments;

FIG. 1B is a plan view illustrating a semiconductor memory device according to some embodiments;

FIG. 2 is a diagram illustrating a semiconductor memory device according to some embodiments;

FIG. 3 is a diagram illustrating a semiconductor memory device according to some embodiments;

FIG. 4A is a diagram illustrating a semiconductor memory device according to some embodiments;

FIG. 4B is a cross-sectional view taken along a cut line 4X-4X′ of FIG. 4A;

FIG. 5A is a diagram illustrating a semiconductor memory device according to some embodiments;

FIG. 5B is a cross-sectional view taken along a cut line 5X-5X′ of FIG. 5A;

FIG. 6A is a diagram illustrating a semiconductor memory device according to some embodiments;

FIG. 6B is a cross-sectional view taken along a cut line 6X-6X′ of FIG. 6A;

FIG. 7A is a diagram illustrating a semiconductor memory device according to some embodiments;

FIG. 7B is a cross-sectional view taken along a cut line 7X-7X′ of FIG. 7A;

FIG. 8 is a flowchart illustrating a method of manufacturing a semiconductor memory device according to some embodiments;

FIGS. 9A to 9D are cross-sectional views illustrating a method of manufacturing a semiconductor memory device according to some embodiments;

FIG. 10 is a flowchart illustrating a method of manufacturing a semiconductor memory device according to some embodiments;

FIG. 11 is a cross-sectional view illustrating a method of manufacturing a semiconductor memory device according to some embodiments;

FIG. 12 is a flowchart illustrating a method of manufacturing a semiconductor memory device according to some embodiments;

FIG. 13 is a cross-sectional view illustrating a method of manufacturing a semiconductor memory device according to some embodiments;

FIG. 14 is a flowchart illustrating a method of manufacturing a semiconductor memory device according to some embodiments;

FIGS. 15A and 15B are cross-sectional views illustrating a method of manufacturing a semiconductor memory device according to some embodiments;

FIG. 16 is a flowchart illustrating a method of manufacturing a semiconductor memory device according to some embodiments;

FIGS. 17A and 17B are cross-sectional views illustrating a method of manufacturing a semiconductor memory device according to some embodiments;

FIG. 18 is a flowchart illustrating a method of manufacturing a semiconductor memory device according to some embodiments;

FIGS. 19A and 19B are cross-sectional views illustrating a method of manufacturing a semiconductor memory device according to some embodiments;

FIG. 20 is a flowchart illustrating a method of manufacturing a semiconductor memory device according to some embodiments; and

FIGS. 21A and 21B are cross-sectional views illustrating a method of manufacturing a semiconductor memory device according to some embodiments.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted.

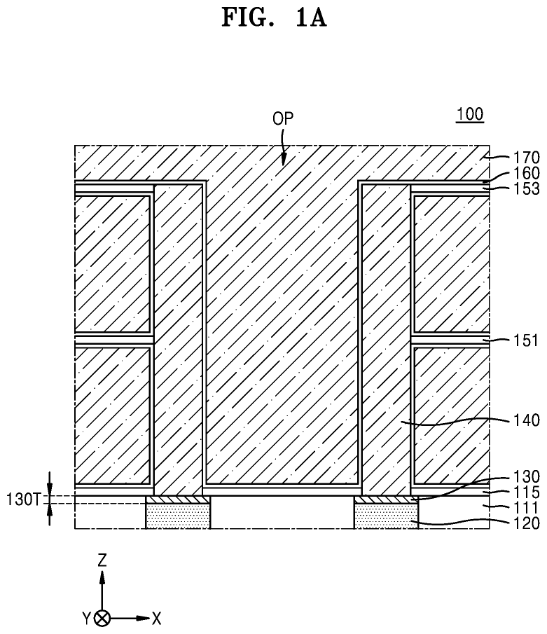

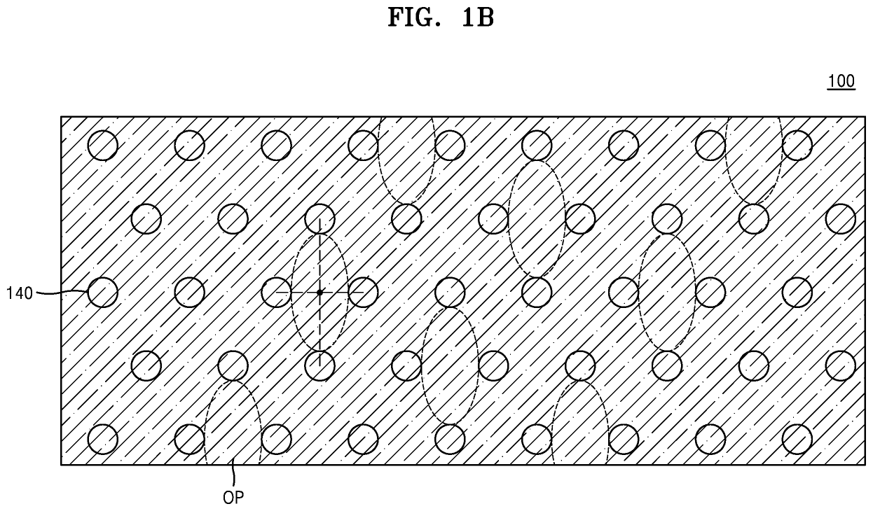

FIG. 1A is a diagram illustrating a semiconductor memory device 100 according to some embodiments. FIG. 1B is a plan view illustrating a semiconductor memory device 100 according to some embodiments. In FIG. 1B, for convenience of description, only a plurality of lower electrodes 140 and a plurality of openings OP are illustrated. As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Referring to FIGS. 1A and 1B, the semiconductor memory device 100 may include an interlayer insulating layer 111, an etch stop layer 115, a plurality of contact pads 120, a plurality of work function adjustment patterns 130, a plurality of lower electrodes 140, a first support structure 151, a second support structure 153, a dielectric layer 160, and an upper electrode 170. The lower electrodes 140 and upper electrode 170 may be electrodes of a capacitor. For example, they may be electrodes of a capacitor of a volatile memory device such as a DRAM chip. For example, the capacitor may be a storage element and may be part of a memory cell of the DRAM chip.

The interlayer insulating layer 111 may be formed of or may include a high-density plasma (HDP) oxide film, TetraEthyl OrthoSilicate (TEOS), Plasma Enhanced TetraEthyl OrthoSilicate (PE-TEOS), O3-TetraEthyl OrthoSilicate (O3-TEOS), Undoped Silicate Glass (USG), Phospho Silicate Glass (PSG), Borosilicate Glass (BSG), BoroPhosphoSilicate Glass (BPSG), Fluoride Silicate Glass (FSG), Spin On Glass (SOG), Tonen SilaZene (TOSZ), or a combination thereof. In addition, or alternatively, the interlayer insulating layer 111 may be formed of or may include silicon nitride, silicon oxynitride, or a material having a low dielectric constant. Here, the material having the low dielectric constant is a material having a lower dielectric constant than that of silicon oxide.

The plurality of contact pads 120 may be embedded in the interlayer insulating layer 111. The plurality of work function adjustment patterns 130 may be embedded in the interlayer insulating layer 111. Side surfaces of each of the plurality of contact pads 120 and the plurality of work function adjustment patterns 130 may be surrounded by the interlayer insulating layer 111. Side surfaces of each of the plurality of contact pads 120 and the plurality of work function adjustment patterns 130 may contact the interlayer insulating layer 111 and may be coplanar with each other. The term “contact,” “contacts,” “contacting,” or “in contact with” as used herein, refers to a direct connection (i.e., touching) unless the context indicates otherwise. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. Top surfaces of the contact pads 120 may be at or below a bottom-most surface of the lower electrodes 140, and may be below a bottom-most surface of the upper electrode 170.

A planar shape of each of the plurality of contact pads 120 (e.g., a top, surface of each of the plurality of contact pads 120) may be approximately circular. Each of the plurality of contact pads 120 may be formed of or may include a material having a high conductivity. Each of the plurality of contact pads 120 may be formed of or may include a material having a high step coverage. The plurality of contact pads 120 may be formed of or may include, for example, tungsten. Contact plugs respectively connected to the plurality of contact pads 120 may be disposed below the plurality of contact pads 120.

The plurality of work function adjustment patterns 130 may be respectively disposed on the plurality of contact pads 120. The plurality of work function adjustment patterns 130 may respectively overlap the plurality of contact pads 120 in a vertical direction (e.g., from a plan view). The plurality of work function adjustment patterns 130 may be disposed between the plurality of contact pads 120 and the plurality of lower electrodes 140. The plurality of work function adjustment patterns 130 may respectively contact the plurality of contact pads 120. The plurality of work function adjustment patterns 130 may be referred to as work function adjustment pad covers or work function adjustment layers.

Here, the vertical direction is a direction perpendicular to an upper surface of the interlayer insulating layer 111, and a horizontal direction is a direction parallel to the upper surface of the interlayer insulating layer 111.

According to some embodiments, a planar shape of each of the plurality of work function adjustment patterns 130 (e.g., from a plan view) may be approximately circular. According to some embodiments, a thickness 130T of each of the plurality of work function adjustment patterns 130 may be in the range of about 1 nm to about 10 nm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The plurality of work function adjustment patterns 130 may adjust equivalent work functions of the plurality of contact pads 120, the plurality of work function adjustment patterns 130, and the plurality of lower electrodes 140. For example, the plurality of work function adjustment patterns 130 are configured to adjust equivalent work functions of structures that include the plurality of contact pads 120, the plurality of work function adjustment patterns 130, and the plurality of lower electrodes 140.

Due to the scaling of the semiconductor memory device 100, the size of each of the plurality of lower electrodes 140 is reduced, and thus, the influence of the work function of the plurality of contact pads 120 on the plurality of lower electrodes 140 is more important. The plurality of contact pads 120 generally include a material (e.g., tungsten) having a lower work function than that of the plurality of lower electrodes 140, which increases a leakage current from the plurality of lower electrodes 140 to the upper electrode 170 through the dielectric layer 160.

According to some embodiments, the plurality of work function adjustment patterns 130 may enhance the equivalent work functions of the plurality of contact pads 120, the plurality of work function adjustment patterns 130, and the plurality of lower electrodes 140. Accordingly, the leakage current from the plurality of lower electrodes 140 to the upper electrode 170 may be reduced.

According to some embodiments, the plurality of work function adjustment patterns 130 may be formed of or may include a material having a work function higher than a work function of a material included in or forming the plurality of contact pads 120.

For example, when the plurality of contact pads 120 are formed of tungsten, because a work function of tungsten is typically less than about 4.6 eV, each of the plurality of work function adjustment patterns 130 may have a work function equal to or greater than about 4.6 eV (e.g., a work function greater than that of tungsten).

According to some embodiments, each of the plurality of work function adjustment patterns 130 may be formed of or may include a metal chalcogenide. According to some embodiments, each of the plurality of work function adjustment patterns 130 may be formed of a metal chalcogenide in a metal phase. Because the plurality of work function adjustment patterns 130 have the metal phase, deterioration in the electrical performance of the semiconductor memory device 100 may be prevented.

In some embodiments, each of the plurality of work function adjustment patterns 130 may be formed of or may include any one of WS₂, MoS₂, WSe₂, MoSe₂, MoS₂, TaTe₂, VTe₂, NbTe₂, TaSe₂, VSe₂, NbSe₂, TaS₂, VS₂, NbS₂, VSe₂, TaS₂, TiTe₂, TiSe₂, TiS₂, and graphene doped with an N-type dopant.

The etch stop layer 115 may be disposed on the interlayer insulating layer 111 and the plurality of work function adjustment patterns 130. The etch stop layer 115 may cover the interlayer insulating layer 111. The etch stop layer 115 may cover a part (e.g., an edge part, or an annular region at an outer circumference) of each of the plurality of work function adjustment patterns 130. The etch stop layer 115 may expose a part of each of the plurality of work function adjustment patterns 130 (e.g., an inner portion).

The etch stop layer 115 may include a material having a high etch selectivity with respect to the interlayer insulating layer 111. For example, the etch stop layer 115 may be formed of or may include a silicon nitride layer or a silicon oxynitride layer.

The plurality of lower electrodes 140 may be disposed on the plurality of work function adjustment patterns 130. The plurality of lower electrodes 140 may penetrate the etch stop layer 115 to contact the plurality of work function adjustment patterns 130. In some embodiments, the plurality of lower electrodes 140 may be arranged in a honeycomb structure, for example, when viewed from a plan view.

The plurality of lower electrodes 140 may be formed of or may include at least one of metal materials, metal nitride layers, or metal silicides. For example, the plurality of lower electrodes 140 may be formed of or may include a refractory metal material, such as cobalt, titanium, nickel, tungsten, or molybdenum. For another example, the plurality of lower electrodes 140 may be formed of or may include a metal nitride, such as a titanium nitride layer (TiN), a titanium silicon nitride layer (TiSiN), a titanium aluminum nitride layer (TiAlN), a tantalum nitride layer (TaN), a tantalum silicon nitride layer (TaSiN), a tantalum aluminum nitride layer (TaAlN), or a tungsten nitride layer (WN). In addition or alternatively, the plurality of lower electrodes 140 may be formed of or may include at least one noble metal material selected from the group consisting of platinum (Pt), ruthenium (Ru), and iridium (Ir). The plurality of lower electrodes 140 may be formed of or may include a noble metal oxide.

The plurality of lower electrodes 140 may have a pillar shape extending in a vertical direction, which may be a direction perpendicular to a top surface of a substrate on which the structure of FIG. 1A is formed. The cross-sections of the lower electrodes 140 (e.g., from a plan view) may be circular or oval.

According to some embodiments, the plurality of contact pads 120, the plurality of work function adjustment patterns 130, and the plurality of lower electrodes 140 may be disposed in a honeycomb structure disposed at vertices and centers of a plurality of hexagons filling a two-dimensional (2D) plane. Each of six vertices of each of the hexagons constituting the honeycomb structure may be a central point of each of the other six adjacent hexagons, and the central point of the hexagon may be a shared vertex of the six hexagons.

The plurality of lower electrodes 140 may be arranged to form a plurality of rows and columns in a plane (e.g., from a plan view). In order to secure space between the plurality of lower electrodes 140, the plurality of lower electrodes 140 constituting one row may be alternately arranged with the plurality of lower electrodes 140 constituting another adjacent row. Accordingly, the space sufficient to provide a dielectric material for forming the dielectric layer 160 may be provided between the plurality of lower electrodes 140.

According to some embodiments, the first support structure 151 may abut and contact mid portions of the plurality of lower electrodes 140, and the second support structure 153 may abut and contact upper portions of the plurality of lower electrodes 140.

According to some embodiments, the first and second support structures 151 and 153 may support the plurality of lower electrodes 140. According to some embodiments, the first and second support structures 151 and 153 support the plurality of lower electrodes 140, thereby preventing the plurality of lower electrodes 140 from collapsing. Each of the first and second support structures 151 and 153 may be described simply as a support, or a support layer.

According to some embodiments, the first and second support structures 151 and 153 may be formed of or may include silicon nitride, but they are not limited thereto. Also, the semiconductor memory device 100 is illustrated as including the two support structures 151 and 153, but the inventive concept is not limited thereto. For example, the semiconductor memory device 100 may include only one of the first and second support structures 151 and 153, or may further include an additional support structure.

The first and second support structures 151 and 153 may be formed as a single body including a plurality of openings OP. Each of the openings OP of the first support structure 151 may overlap a corresponding one of the openings OP of the second support structure 153 in a vertical direction (e.g., in a Z direction). The first and second support structures 151 and 153 may have a flat plate shape spaced apart from the upper surface of the interlayer insulating layer 111. The first support structure 151 may be disposed between the second support structure 153 and the upper surface of the interlayer insulating layer 111.

The plurality of openings OP may be horizontally disposed along rows and columns (e.g., in X and Y directions). For example, in some embodiments, as shown in FIG. 1B, a planar shape of each of the plurality of openings OP may be oval, and the center of each of the plurality of openings OP may be disposed to overlap with the center of a diamond including four adjacent lower electrodes 140. In this case, the plurality of openings OP may open the four lower electrodes 140.

For another example, the planar shape each of the plurality of openings OP may be circular, and the center of each of the plurality of openings OP may overlap with the center of a regular triangle including the three adjacent lower electrodes 140. In this case, the plurality of openings OP may open the three lower electrodes 140.

Here, when it is stated that the plurality of openings OP “open” the plurality of lower electrodes 140, this means that the first support structure 151 and the second support structure 153 before the dielectric layer 160 and the upper electrode 170 are deposited expose parts of the plurality of lower electrodes 140 at the same level.

The dielectric layer 160 may cover the plurality of lower electrodes 140, the etch stop layer 115, the first support structure 151, and the second support structure 153. The dielectric layer 160 may have a uniform thickness. The dielectric layer 160 may insulate the plurality of lower electrodes 140 from the upper electrode 170.

The dielectric layer 160 may be formed of or may include a high-k material. The dielectric layer 160 may be formed of or may include, for example, any one single layer selected from a combination of a metal oxide, such as HfO₂, ZrO₂, Al₂O₃, La₂O₃, Ta₂O₃, and a dielectric material having a perovskite structure, such as SrTiO₃(STO), BaTiO₃, PZT, PLZT, or a combination thereof. The dielectric layer 160 may include TiO₂.

The upper electrode 170 may be formed of or may include at least one of silicon doped with impurities, metal materials, metal nitride layers, or metal silicides. The upper electrode 170 may be formed of or may include the same material as that of the plurality of lower electrodes 140, but is not limited thereto.

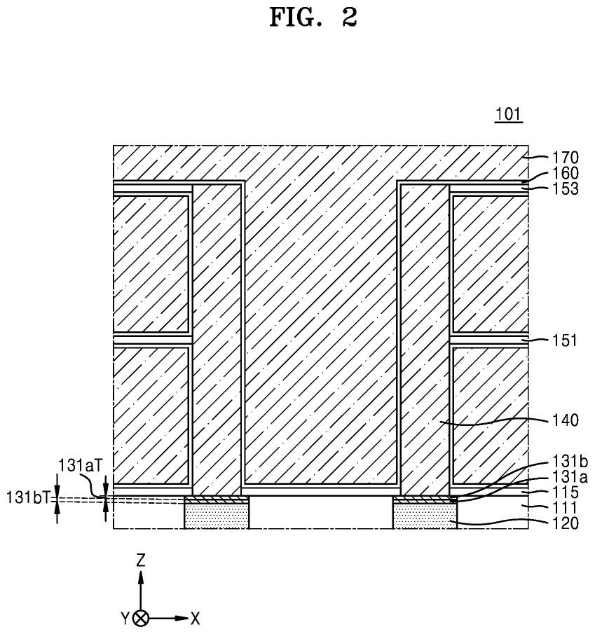

FIG. 2 is a diagram illustrating a semiconductor memory device 101 according to some embodiments.

Referring to FIG. 2, the semiconductor memory device 101 may include the interlayer insulating layer 111, the etch stop layer 115, the plurality of contact pads 120, a plurality of first work function adjustment patterns 131a, a plurality of second work function adjustment patterns 131b, the plurality of lower electrodes 140, the first support structure 151, the second support structure 153, the dielectric layer 160, and the upper electrode 170.

The interlayer insulating layer 111, the etch stop layer 115, the plurality of contact pads 120, the plurality of lower electrodes 140, the first support structure 151, the second support structure 153, the dielectric layer 160, and the upper electrode 170 are substantially the same as those described with reference to FIG. 1A, and thus redundant descriptions thereof will be omitted.

The plurality of first function adjustment patterns 131a may be respectively disposed on the plurality of contact pads 120. The plurality of second function adjustment patterns 131b may be respectively disposed on the plurality of first function adjustment patterns 131a. The plurality of first and second work function adjustment patterns 131a and 131b may overlap the plurality of contact pads 120 in a vertical direction. It will be understood that when an element is referred to as being “on” or “connected” or “coupled” to another element, it can be directly on or connected or coupled to the other element or intervening elements may be present. In contrast, when an element is referred to as being “directly on” or “directly connected” or “directly coupled” to another element, there are no intervening elements present at a point of contact.

The plurality of first and second work function adjustment patterns 131a and 131b may be embedded in the interlayer insulating layer 111. The plurality of first work function adjustment patterns 131a and the plurality of second work function adjustment patterns 131b may be horizontally surrounded by the interlayer insulating layer 111. Side surfaces of each of the plurality of first work function adjustment patterns 131a and the plurality of second work function adjustment patterns 131b may contact the interlayer insulating layer 111.

The plurality of first and second work function adjustment patterns 131a and 131b may be disposed between the plurality of contact pads 120 and the plurality of lower electrodes 140. The plurality of first work function adjustment patterns 131a may be disposed between the plurality of contact pads 120 and the plurality of second work function adjustment patterns 131b. The plurality of second work function adjustment patterns 131b may be disposed between the plurality of lower electrodes 140 and the plurality of first work function adjustment patterns 131a.

The plurality of first work function adjustment patterns 131a may contact the plurality of contact pads 120. The plurality of second work function adjustment patterns 131b may contact the plurality of first work function adjustment patterns 131a. The plurality of second work function adjustment patterns 131b may contact the plurality of lower electrodes 140.

According to some embodiments, a planar shape of each of the plurality of first and second work function adjustment patterns 131a and 131b may be approximately circular. According to some embodiments, a thickness 131aT of each of the plurality of first work function adjustment patterns 131a and a thickness 131bT of each of the plurality of second work function adjustment patterns 131b may be in the range of about 1 nm to about 10 nm. According to some embodiments, the sum of the thickness 131aT of each of the plurality of first work function adjustment patterns 131a and the thickness 131bT of each of the plurality of second work function adjustment patterns 131b may be about 1 nm to about 10 nm.

The plurality of first and second work function adjustment patterns 131a and 131b may adjust equivalent work functions of the plurality of contact pads 120, the plurality of first and second work function adjustment patterns 131a and 131b, and the plurality of lower electrodes 140. According to some embodiments, the plurality of first and second work function adjustment patterns 131a and 131b may enhance the equivalent work functions of the plurality of contact pads 120, the plurality of first and second work function adjustment patterns 131a and 131b, and the plurality of lower electrodes 140.

According to some embodiments, the plurality of first and second work function adjustment patterns 131a and 131b may include a material having a work function higher than that of a material included in the plurality of contact pads 120.

For example, when the plurality of contact pads 120 are formed of tungsten, each of the plurality of first and second work function adjustment patterns 131a and 131b may be formed of a material having a work function equal to or greater than about 4.6 eV.

According to some embodiments, each of the plurality of first and second work function adjustment patterns 131a and 131b may be formed of or may include a metal chalcogenide. According to some embodiments, each of the plurality of first and second work function adjustment patterns 131a and 131b may be formed of or may include the metal chalcogenide in a metal phase. The plurality of first and second work function adjustment patterns 131a and 131b may have the metal phase, and thus, deterioration of the electrical performance of the semiconductor memory device 101 may be prevented.

According to some embodiments, the plurality of first and second work function adjustment patterns 131a and 131b may be formed of or may include different materials. For example, each of the plurality of first and second work function adjustment patterns 131a and 131b may include one or more of materials described in relation to the work function patterns 130 of FIG. 1A, so that the first work function adjustment patterns 131a are formed of a different material from the second work function adjustment patterns 131b.

According to some embodiments, the plurality of first and second work function adjustment patterns 131a and 131b including different materials are provided, thereby precisely adjusting the equivalent work functions of the plurality of contact pads 120, the plurality of first and second work function adjustment patterns 131a and 131b, and the plurality of lower electrodes 140.

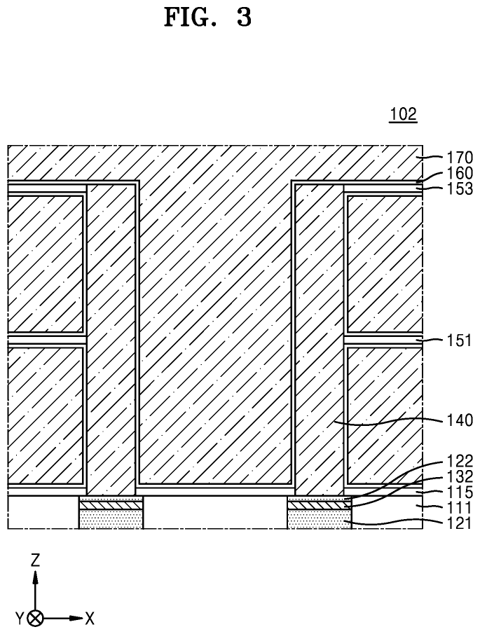

FIG. 3 is a diagram illustrating a semiconductor memory device 102 according to some embodiments.

Referring to FIG. 3, the semiconductor memory device 102 may include the interlayer insulating layer 111, the etch stop layer 115, a plurality of first contact pads 121, a plurality of work function adjustment patterns 132, a plurality second contact pads 122, the plurality of lower electrodes 140, the first support structure 151, the second support structure 153, the dielectric layer 160, and the upper electrode 170.

The interlayer insulating layer 111, the etch stop layer 115, the plurality of lower electrodes 140, the first support structure 151, the second support structure 153, the dielectric layer 160, and the upper electrode 170 are substantially the same as those described with reference to FIG. 1A, and thus redundant descriptions thereof will be omitted.

The plurality of first contact pads 121, the plurality of work function adjustment patterns 132, and the plurality of second contact pads 122 may be embedded in the interlayer insulating layer 111. Side surfaces of each of the plurality of first contact pads 121 and second contact pads 122 and the plurality of work function adjustment patterns 132 may be surrounded by the interlayer insulating layer 111. Side surfaces of each of the plurality of first contact pads 121 and second contact pads 122 and the plurality of work function adjustment patterns 132 may contact the interlayer insulating layer 111.

A planar shape of each of the plurality of first contact pads 121, the plurality of work function adjustment patterns 132, and the plurality of second contact pads 122 may be approximately circular. Each of the plurality of first and second contact pads 121 and 122 may include a material having a high conductivity. Each of the plurality of first and second contact pads 121 and 122 may include a material having a high step coverage. The plurality of first and second contact pads 121 and 122 may include, for example, tungsten. Contact plugs connected to the plurality of first contact pads 121 may be respectively disposed below the plurality of first contact pads 121.

The plurality of work function adjustment patterns 132 are substantially similar to the plurality of work function adjustment patterns 130 of FIG. 1A, but may be disposed between the plurality of first contact pads 121 and the plurality of second contact pads 122.

The plurality of work function adjustment patterns 132 may vertically overlap respectively the plurality of first contact pads 121 and the plurality of second contact pads 122. The plurality of work function adjustment patterns 132 may be spaced apart from the plurality of lower electrodes 140 with the plurality of second contact pads 122 disposed therebetween. The plurality of lower electrodes 140 may respectively contact the plurality of second contact pads 122.

According to some embodiments, the plurality of second contact pads 122 are additionally provided on the plurality of work function adjustment patterns 132, thereby minimizing the influence of a subsequent process due to a material change of landing pads (i.e., elements contacted by the plurality of lower electrodes 140) of the plurality of lower electrodes 140. For example, the plurality of work function adjustment patterns 132 may be passivated with the plurality of second contact pads 122, thereby preventing an undesirable change in the electrical characteristic of the semiconductor memory device 102. Accordingly, the reliability of the semiconductor memory device 102 may be improved.

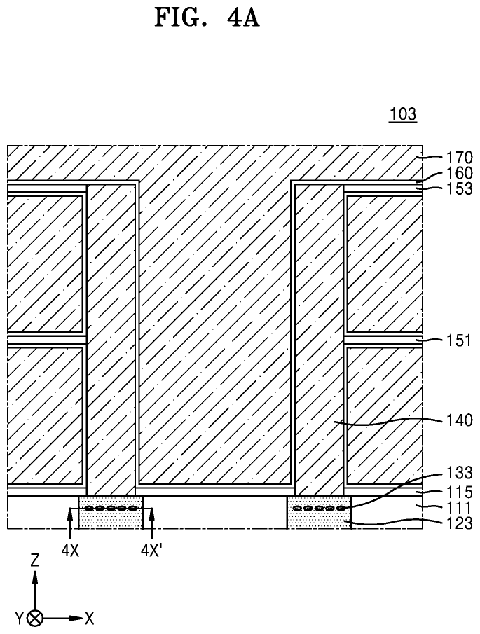

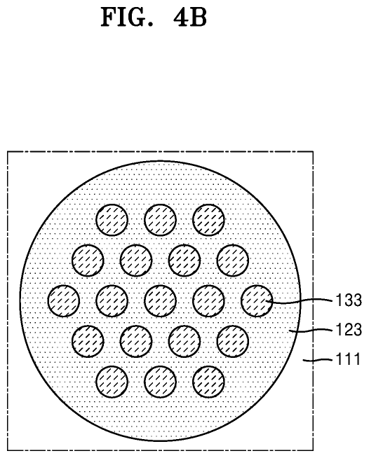

FIG. 4A is a diagram illustrating a semiconductor memory device 103 according to some embodiments.

FIG. 4B is a cross-sectional view taken along a cut line 4X-4X′ of FIG. 4A.

Referring to FIGS. 4A and 4B, the semiconductor memory device 103 may include the interlayer insulating layer 111, the etch stop layer 115, a plurality of contact pads 123, a plurality of work function adjustment clusters 133, the plurality of lower electrodes 140, the first support structure 151, the second support structure 153, the dielectric layer 160, and the upper electrode 170.

The interlayer insulating layer 111, the etch stop layer 115, the plurality of lower electrodes 140, the first support structure 151, the second support structure 153, the dielectric layer 160, and the upper electrode 170 are substantially the same as those described with reference to FIG. 1A, and thus redundant descriptions thereof will be omitted.

The plurality of contact pads 123 may be embedded in the interlayer insulating layer 111. Side surfaces of each of the plurality of contact pads 123 may be surrounded by the interlayer insulating layer 111. Side surfaces of each of the plurality of contact pads 123 may contact the interlayer insulating layer 111.

A planar shape of each of the plurality of contact pads 123 may be approximately circular. Each of the plurality of contact pads 123 may include a material having a high conductivity. Each of the plurality of contact pads 123 may include a material having a high step coverage. Each of the plurality of contact pads 123 may include, for example, tungsten. Contact plugs connected to the plurality of contact pads 123 may be respectively disposed below the plurality of contact pads 123. The plurality of contact pads 123 may be respectively connected to the plurality of lower electrodes 140.

The plurality of work function adjustment clusters 133 may be embedded in the plurality of contact pads 123. Each cluster of the plurality of work function adjustment clusters 133 may be three-dimensionally surrounded by the plurality of contact pads 123. The plurality of work function adjustment clusters 133 may contact the plurality of contact pads 123, and may be considered to be part of the contact pads 123.

The plurality of work function adjustment clusters 133 may not form a continuous film, and accordingly, each of the plurality of work function adjustment clusters 133 may have an irregular shape, and the plurality of work function adjustment clusters 133 may be horizontally spaced apart from each other. Also, the plurality of work function adjustment clusters 133 may be arranged irregularly (e.g., at an irregular density). According to some embodiments, the plurality of work function adjustment clusters 133 may be also respectively disposed at the same level (e.g., at a vertical distance) from lower surfaces of the plurality of contact pads 123.

The plurality of work function adjustment clusters 133 may each correspond to a respective contact pad of the plurality of contact pads 123. For example, each work function adjustment cluster of the plurality of work function adjustment clusters 133 corresponds to one of the plurality of contact pads 123. The plurality of work function adjustment clusters 133 may be embedded in a respective plurality of contact pads 123. Vertical levels (i.e., a distance from the upper surface of the interlayer insulating layer 111) of the plurality of work function adjustment clusters 133 may be substantially the same.

The plurality of work function adjustment clusters 133 are three-dimensionally covered with the plurality of contact pads 123, thereby minimizing the influence of a subsequent process due to a material change of a landing pad of the plurality of lower electrodes 140. For example, the plurality of work function adjustment clusters 133 are passivated with the plurality of second contact pads 123, thereby preventing a change in the electrical characteristic of the semiconductor memory device 103. Accordingly, the reliability of the semiconductor memory device 103 may be improved.

According to some embodiments, the composition and characteristic (e.g., a work function) of each of the plurality of work function adjustment clusters 133 are similar to the composition and characteristic of each of the plurality of work function adjustment patterns 130 described with reference to FIG. 1A, and thus redundant descriptions thereof will be omitted. Each work function adjustment cluster 133 may include a set of pieces of work function adjustment material, arranged in a cluster, so that they are separated from each other, such as depicted in FIG. 4B.

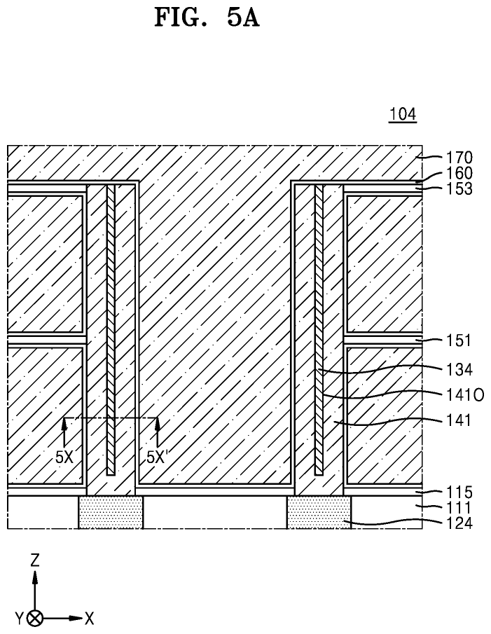

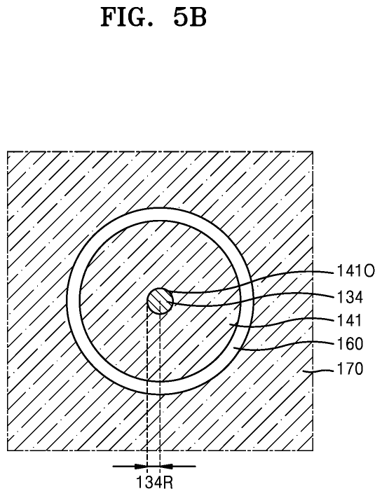

FIG. 5A is a diagram illustrating a semiconductor memory device 104 according to some embodiments.

FIG. 5B is a cross-sectional view taken along a cut line 5X-5X′ of FIG. 5A.

Referring to FIGS. 5A and 5B, the semiconductor memory device 104 may include the interlayer insulating layer 111, the etch stop layer 115, a plurality of contact pads 124, a plurality of lower electrodes 141, a plurality of work function adjustment patterns 134, the first support structure 151, the second support structure 153, the dielectric layer 160, and the upper electrode 170.

The interlayer insulating layer 111, the etch stop layer 115, the first support structure 151, the second support structure 153, the dielectric layer 160, and the upper electrode 170 are substantially the same as those described with reference to FIG. 1A, and thus redundant descriptions thereof will be omitted.

The plurality of contact pads 124 may be embedded in the interlayer insulating layer 111. Side surfaces of each of the plurality of contact pads 124 may be surrounded by the interlayer insulating layer 111. Side surfaces of each of the plurality of contact pads 124 may contact the interlayer insulating layer 111.

A planar shape of each of the plurality of contact pads 124 may be approximately circular. Each of the plurality of contact pads 124 may be formed of or may include a material having a high conductivity. Each of the plurality of contact pads 124 may be formed of or may include a material having a high step coverage. Each of the plurality of contact pads 124 may be formed of or may include, for example, tungsten. Contact plugs connected to the plurality of contact pads 124 may be disposed below the plurality of contact pads 124. The plurality of contact pads 124 may be connected to the plurality of lower electrodes 141. The plurality of contact pads 124 may respectively contact the plurality of lower electrodes 141.

The plurality of lower electrodes 141 may have a cup shape. The plurality of lower electrodes 141 may have a uniform thickness, and accordingly, the plurality of lower electrodes 141 may have a conformal structure. Cross-sections of the plurality of lower electrodes 141 may have a ring shape.

The plurality of work function adjustment patterns 134 may be disposed in openings 1410 defined by the cup shape of the plurality of lower electrodes 141. The plurality of work function adjustment patterns 134 may be embedded in the plurality of lower electrodes 141. The plurality of work function adjustment patterns 134 may respectively fill the openings 1410. The plurality of work function adjustment patterns 134 may completely and respectively fill the openings 1410. Upper surfaces of the plurality of work function adjustment patterns 134 may be respectively coplanar with upper surfaces of the plurality of lower electrodes 141.

The plurality of work function adjustment patterns 134 may have a bar shape. For example, cross-sections of the plurality of work function adjustment patterns 134 may be circular. According to some embodiments, a radius 134R of each of the plurality of work function adjustment patterns 134 may be in the range of about 1 nm to about 10 nm. For another example, the cross-sections of the plurality of work function adjustment patterns 134 may have an oval shape.

Lower surfaces and side surfaces of the plurality of work function adjustment patterns 134 may be covered by the plurality of lower electrodes 141. Lower surfaces and side surfaces of the plurality of work function adjustment patterns 134 may contact the plurality of lower electrodes 141. The plurality of contact pads 124 may be spaced apart from the plurality of work function adjustment patterns 134, with the lower electrodes 141 therebetween.

The plurality of work function adjustment patterns 134 may adjust equivalent work functions of the plurality of contact pads 124, the plurality of work function adjustment patterns 134, and the plurality of lower electrodes 141. According to some embodiments, the plurality of work function adjustment patterns 134 may enhance the equivalent work functions of the plurality of contact pads 124, the plurality of work function adjustment patterns 134, and the plurality of lower electrodes 141. Accordingly, leakage current from the plurality of lower electrodes 141 to the upper electrode 170 may be reduced.

According to some embodiments, the compositions and characteristics (e.g., work functions) of the plurality of work function adjustment patterns 134 are similar to the compositions and characteristics of the plurality of work function adjustment patterns 130 described with reference to FIG. 1A, and thus redundant descriptions thereof will be omitted.

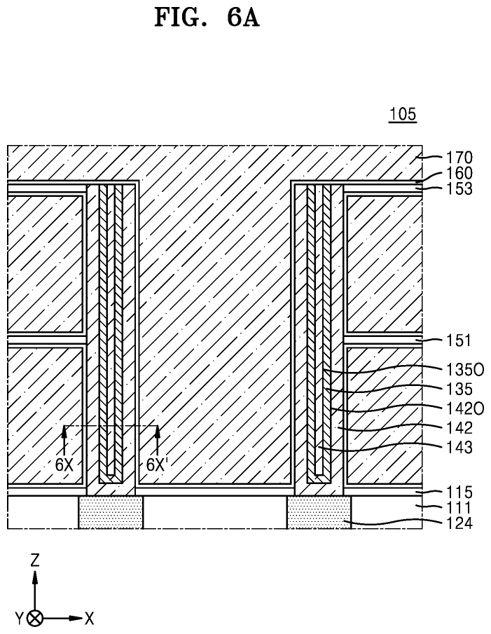

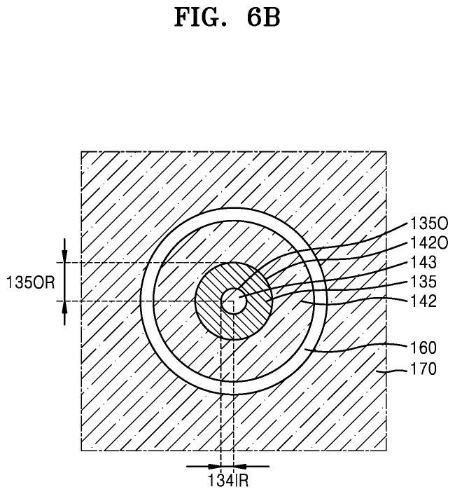

FIG. 6A is a diagram illustrating a semiconductor memory device 105 according to some embodiments.

FIG. 6B is a cross-sectional view taken along a cut line 6X-6X′ of FIG. 6A.

Referring to FIGS. 6A and 6B, the semiconductor memory device 105 may include the interlayer insulating layer 111, the etch stop layer 115, the plurality of contact pads 124, a plurality of first lower electrodes 142, a plurality of work function adjustment patterns 135, a plurality of second lower electrodes 143, the first support structure 151, the second support structure 153, the dielectric layer 160, and the upper electrode 170.

The interlayer insulating layer 111, the etch stop layer 115, the plurality of contact pads 124, the first support structure 151, the second support structure 153, the dielectric layer 160, and the upper electrode 170 are substantially the same as those described with reference to FIG. 1A, and thus, redundant descriptions thereof will be omitted.

The plurality of first lower electrodes 142 may have a cup shape. Each of the plurality of first lower electrodes 142 may have a uniform thickness, and accordingly, each of the first lower electrodes 142 may have a conformal structure. Cross-sections of the plurality of first lower electrodes 142 may have a ring shape.

The plurality of work function adjustment patterns 135 may be respectively embedded in the plurality of first lower electrodes 142. The plurality of work function adjustment patterns 135 may be disposed in openings 1420 defined by the cup shape of the plurality of first lower electrodes 142. The plurality of work function adjustment patterns 135 may fill the openings 1420. The plurality of work function adjustment patterns 135 may partially fill the openings 1420. Upper surfaces of the plurality of work function adjustment patterns 135 may be coplanar with upper surfaces of the plurality of first lower electrodes 142.

Lower surfaces and side surfaces of the plurality of work function adjustment patterns 135 may be covered by the plurality of first lower electrodes 142. Lower surfaces and side surfaces of the plurality of work function adjustment patterns 135 may contact the plurality of first lower electrodes 142.

The plurality of work function adjustment patterns 135 may have a cup shape. Each of the plurality of work function adjustment patterns 135 may have a uniform thickness, and accordingly, each of the work function adjustment patterns 135 may have a conformal structure. Cross-sections of the plurality of work function adjustment patterns 135 may have a ring shape. According to some embodiments, a difference between an outer radius 1350R and an inner radius 13518 of each of the plurality of work function adjustment patterns 135 may be in the range of about 1 nm to about 10 nm.

The plurality of second lower electrodes 143 may be embedded in the plurality of work function adjustment patterns 135. The plurality of second lower electrodes 143 may be disposed in openings 1350 defined by the cup shape of the plurality of work function adjustment patterns 135. The plurality of second lower electrodes 143 may fill the openings 1350. The plurality of second lower electrodes 143 may completely fill the openings 1350.

Lower surfaces and side surfaces of the plurality of second lower electrodes 143 may contact the plurality of work function adjustment patterns 135. Upper surfaces of the plurality of work function adjustment patterns 135 may be coplanar with upper surfaces of the plurality of second lower electrodes 143.

The plurality of second lower electrodes 143 may have a bar shape. For example, cross-sections of the plurality of second lower electrodes 143 may be circular. For another example, cross-sections of the plurality of second lower electrodes 143 may have an oval shape.

The plurality of work function adjustment patterns 135 may adjust equivalent work functions of the plurality of contact pads 124, the plurality of work function adjustment patterns 135, and the plurality of first and second lower electrodes 142 and 143. According to some embodiments, the plurality of work function adjustment patterns 135 may enhance the equivalent work functions of the plurality of contact pads 124, the plurality of work function adjustment patterns 135, and the plurality of first and second lower electrodes 142 and 143. Accordingly, leakage current from the plurality of first lower electrodes 142 to the upper electrode 170 may be reduced.

According to some embodiments, the compositions and characteristics (e.g., work functions) of the plurality of work function adjustment patterns 135 are similar to the compositions and characteristics of the plurality of work function adjustment patterns 130 described with reference to FIG. 1A, and thus, redundant descriptions thereof will be omitted.

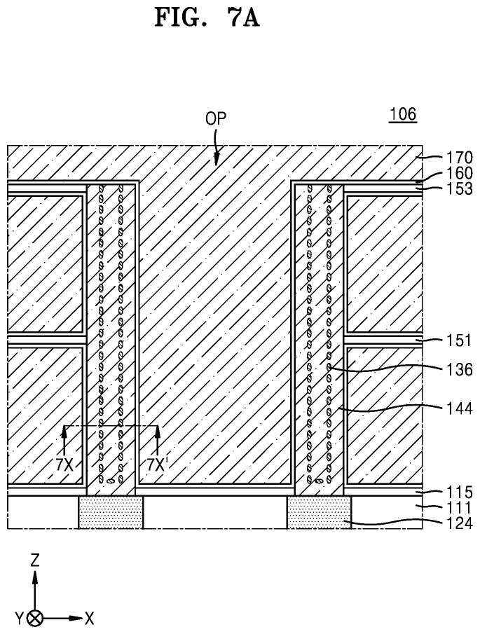

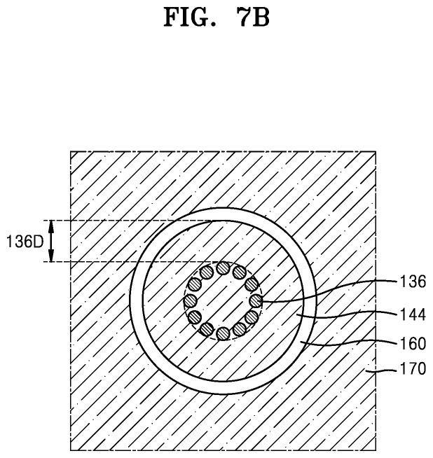

FIG. 7A is a diagram illustrating a semiconductor memory device 106 according to some embodiments.

FIG. 7B is a cross-sectional view taken along a cut line 7X-7X′ of FIG. 7A.

Referring to FIGS. 7A and 7B, the semiconductor memory device 106 may include the interlayer insulating layer 111, the etch stop layer 115, the plurality of contact pads 124, a plurality of lower electrodes 144, a plurality of work function adjustment clusters 136, the first support structure 151, the second support structure 153, the dielectric layer 160, and the upper electrode 170.

The interlayer insulating layer 111, the etch stop layer 115, the plurality of contact pads 124, the first support structure 151, the second support structure 153, the dielectric layer 160, and the upper electrode 170 are substantially the same as those described with reference to FIG. 1A, and thus, redundant descriptions thereof will be omitted.

The plurality of work function adjustment clusters 136 may be embedded in the plurality of lower electrodes 144, respectively. The plurality of work function adjustment clusters 136 may be three-dimensionally surrounded by the plurality of lower electrodes 144. The plurality of work function adjustment clusters 136 may contact the plurality of lower electrodes 144.

The plurality of work function adjustment clusters 136 may be in a state before forming a continuous film, and accordingly, each of the plurality of work function adjustment clusters 136 may have an irregular shape, and the pieces of each cluster of the plurality of work function adjustment clusters 136 may be spaced apart from each other horizontally and vertically.

In the cross-sectional view, distances 136D from outer walls of the plurality of lower electrodes 144 to the plurality of work function adjustment clusters 136 may be substantially the same. Here, the distance 136D is defined as the shortest distance. Accordingly, in the cross-sectional view, the arrangement of pieces of each of the plurality of work function adjustment clusters 136 may be approximately a ring shape.

The plurality of work function adjustment clusters 136 may each correspond to each of the plurality of lower electrodes 144. For Example, each of the plurality of work function adjustment clusters 136 may correspond to one of the plurality of lower electrodes 144. Each cluster of the plurality of work function adjustment clusters 133 may be embedded in a respective lower electrode of the plurality of lower electrodes 144. Pieces of the plurality of work function adjustment clusters 136 may be arranged in a vertical direction.

According to some embodiments, the composition and characteristic (e.g., a work function) of each of the plurality of work function adjustment clusters 136 are similar to the composition and characteristic of each of the plurality of work function adjustment patterns 130 described with reference to FIG. 1A, and thus, redundant descriptions thereof will be omitted.

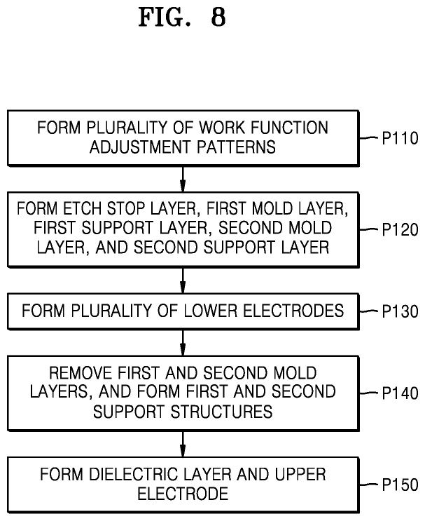

FIG. 8 is a flowchart illustrating a method of manufacturing a semiconductor memory device according to some embodiments.

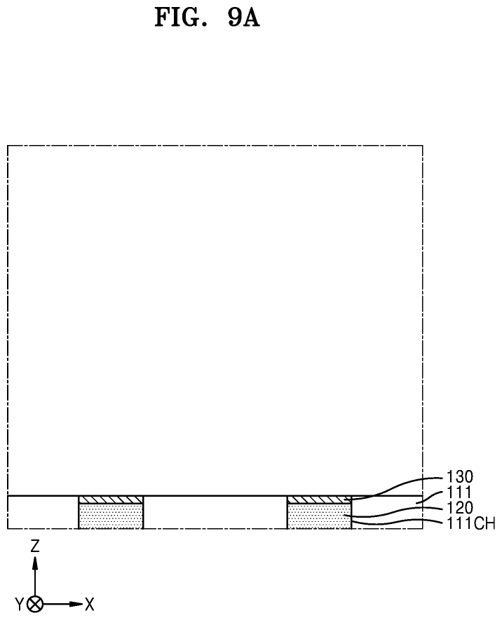

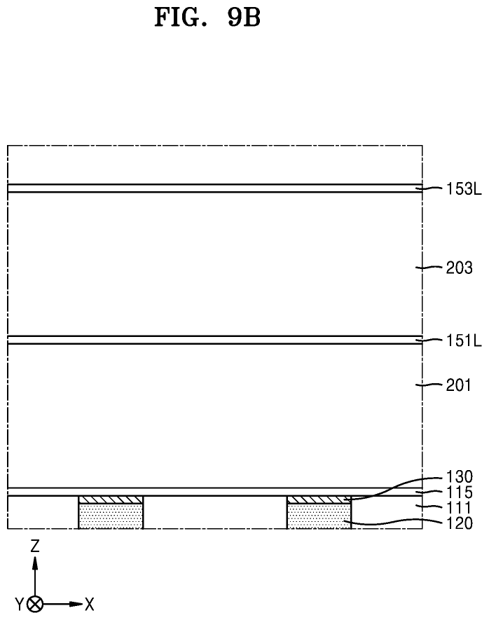

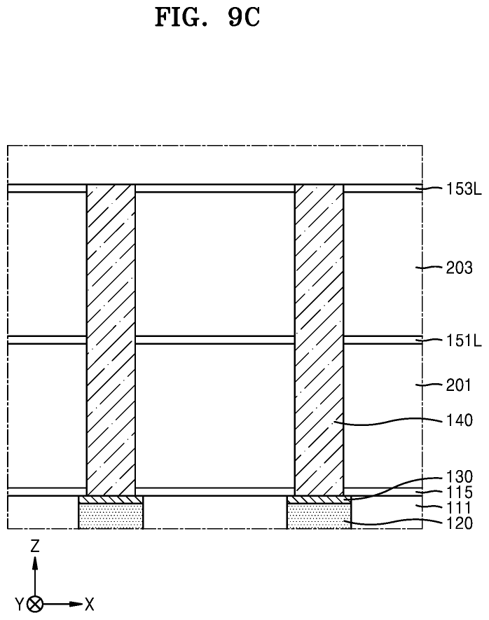

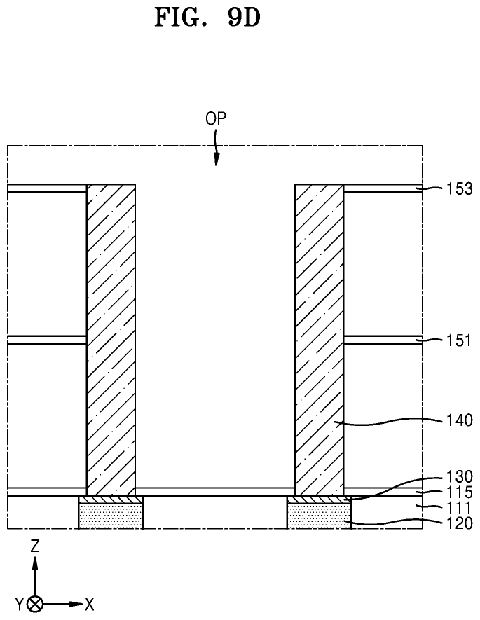

FIGS. 9A to 9D are cross-sectional views illustrating the method of manufacturing the semiconductor memory device according to some embodiments.

Referring to FIGS. 8 and 9A, in P110, the plurality of work function adjustment patterns 130 are formed.

Before the formation of the plurality of work function adjustment patterns 130, the interlayer insulating layer 111 and the plurality of contact pads 120 are formed.

According to some embodiments, the interlayer insulating layer 111 may include substantially the same material as that described with reference to FIG. 1A. According to some embodiments, the interlayer insulating layer 111 may be provided by a chemical vapor deposition (CVD) process. The interlayer insulating layer 111 may be formed on, for example, a substrate, such as a semiconductor wafer.

A plurality of contact holes 111CH may be formed by partially etching the interlayer insulating layer 111. The contact pads 120 may be formed, by providing a conductive material layer to partially fill the contact holes 111CH. According to some embodiments, the contact pads 120 may be formed by CVD and physical vapor deposition (PVD) processes.

Subsequently, the plurality of work function adjustment patterns 130 may be formed to fill the remaining parts of the contact holes 111CH of the interlayer insulating layer 111. Accordingly, upper surfaces of the work function adjustment patterns 130 may form a coplanar surface with the interlayer insulating layer 111. The work function adjustment patterns 130 may be formed by, for example, the CVD process.

Next, referring to FIGS. 8 and 9B, in P120, the etch stop layer 115, a first mold layer 201, a first support layer 151L, a second mold layer 203, and a second support layer 153L are formed.

In some embodiments, the etch stop layer 115 may be formed on the interlayer insulating layer 111 and the work function adjustment patterns 130. The etch stop layer 115 may include a material having a high etch selectivity with respect to the first and second mold layers 201 and 203 that will be described below.

According to some embodiments, the etch stop layer 115 may be formed by the CVD process, a low pressure CVD process, a plasma enhanced CVD (PECVD) process, a PVD process, or an atomic layer deposition (ALD) process, etc.

The first mold layer 201, the first support layer 151L, the second mold layer 203, and the second support layer 153L may be sequentially formed on the etch stop layer 115.

According to some embodiments, each of the first and second mold layers 201 and 203 may be formed of or include an oxide layer. According to some embodiments, each of the first and second mold layers 201 and 203 may be formed of or include an oxide layer, such as Boro Phosphorous Silicate Glass (BPSG), Spin On Dielectric (SOD), Phosphorous Silicate Glass (PSG), Low Pressure Tetra Ethyl Ortho Silicate (LPTEOS) or Plasma Enhanced Tetra Ethyl Ortho Silicate (PETEOS). According to some embodiments, the sum of thicknesses of the first and second mold layers 201 and 203 (e.g., in a vertical direction, or Z-direction) may be about 500 nm to about 4000 nm, but it is not limited thereto. According to some embodiments, the first and second mold layers 201 and 203 may be formed by the CVD process or a spin coating process.

According to some embodiments, the first support layer 151L and the second support layer 153L may be formed of or include a silicon nitride film or an undoped polysilicon film. According to some embodiments, the first support layer 151L and the second support layer 153L may have a thickness of about 20 nm to about 150 nm.

Next, referring to FIGS. 8 and 9C, in P130, the plurality of lower electrodes 140 may be formed.

An etch mask may be formed on the second support layer 153L, the etch stop layer 115, the first mold layer 201, the first support layer 151L, the second mold layer 203, and the second support layer 153L may be etched using the etch mask. Accordingly, a plurality of holes exposing an upper surface of each of the plurality of work function adjustment patterns 130 may be formed.

The etch mask may include, for example, a photoresist pattern and a hard mask pattern. The photoresist pattern may be formed by forming a hardmask layer, a selective antireflection coating layer, and a photoresist layer on the second support layer 153L, and patterning the photoresist layer using a photolithography process. The etch mask may be provided, by patterning the hardmask layer using the photoresist pattern.

Then, a conductive material may be provided to fill the plurality of holes and separated by performing metal chemical mechanical polishing (CMP), and thus, the plurality of lower electrodes 140 may be formed. The upper surface of the second support layer 153L may be, for example, an end point of the metal CMP.

Subsequently, referring to FIGS. 8, 9C and 9D, in P140, the first and second mold layers 201 and 203 are removed, and the first and second support structures 151 and 153 are formed.

According to some embodiments, a part of the second support layer 153L may be removed through the photolithography process and an etching process, and accordingly, the second support structure 153 may be formed. Accordingly, openings OP may be formed to expose side surfaces of the lower electrodes 140. The second mold layer 203 may be removed by providing an etching chemical through the openings OP. The etching chemical may include, for example, hydrofluoric acid or a buffered oxide etchant (BOE) solution.

Similarly, a part of the first support layer 151L on the openings OP may be removed, and accordingly, the first support structure 151 may be formed. The first support structure 151 may not completely cover side surfaces of each of the lower electrodes 140. Accordingly, the first mold layer 201 may be removed by providing the etching chemical through the openings OP.

While a wet etching process is being performed, the first and second support structures 151 and 153 may support the lower electrodes 140. In addition, the etch stop layer 115 may prevent the interlayer insulating layer 111 from being etched, in addition to supporting the lower electrodes 140.

Next, referring to FIGS. 8 and 1, in P150, the dielectric layer 160 and the upper electrode 170 are formed.

The dielectric layer 160 may be conformally formed on the upper surface of the etch stop layer 115, the exposed surfaces of the support structures 151 and 153, and the exposed surfaces of the plurality of lower electrodes 140.

The upper electrode 170 may be formed on the dielectric layer 160. According to some embodiments, the upper electrode 170 may be sufficiently provided to fill space surrounded by the dielectric layer 160. According to some embodiments, the upper electrode 170 may have a cap shape that covers the plurality of lower electrodes 140.

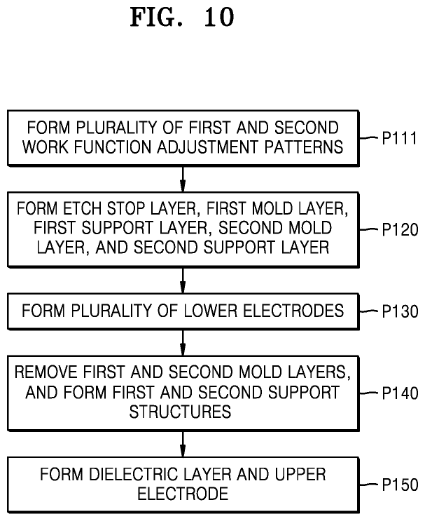

FIG. 10 is a flowchart illustrating a method of manufacturing a semiconductor memory device according to some embodiments.

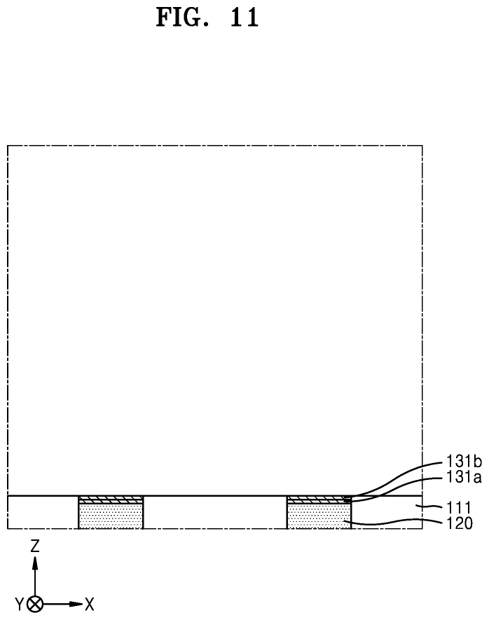

FIG. 11 is a cross-sectional view illustrating the method of manufacturing the semiconductor memory device according to some embodiments.

Referring to FIGS. 10 and 11, in P111, the plurality of first and second work function adjustment patterns 131a and 131b are formed.

After the first work function adjustment patterns 131a are formed by a first CVD using a first source gas, the second work function adjustment patterns 131b may be formed through a second CVD using a second source gas.

For example, the first and second CVDs may be performed in the same CVD facility. For another example, the first CVD and the second CVD may be performed in different CVD facilities. For example, the first work function adjustment patterns 131a may be formed in a first CVD facility, then, a workpiece (e.g., a wafer) may be transferred to a second CVD facility, and the second work function patterns 131b may be formed in the second CVD facility.

P120 to P150 are substantially the same as those described with reference to FIGS. 8 to 9D, and thus, redundant descriptions thereof will be omitted.

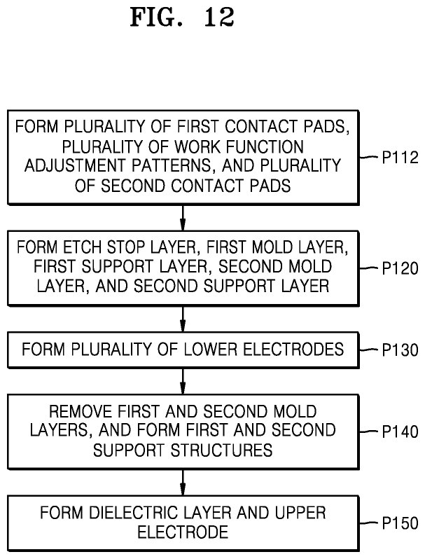

FIG. 12 is a flowchart illustrating a method of manufacturing a semiconductor memory device according to some embodiments.

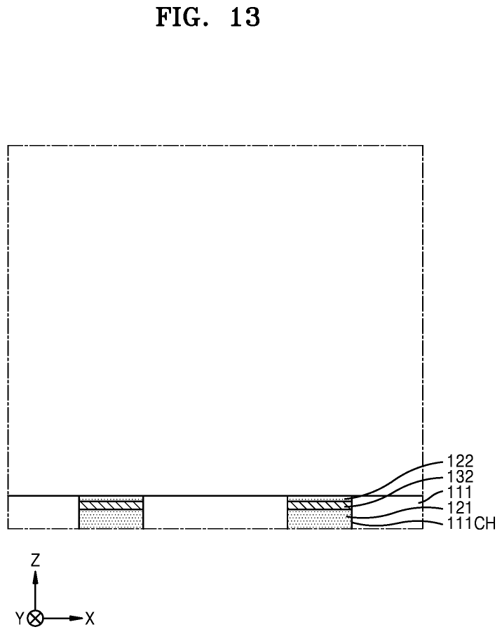

FIG. 13 is a cross-sectional view illustrating the method of manufacturing the semiconductor memory device according to some embodiments.

Referring to FIGS. 12 and 13, in P112, the plurality of first contact pads 121, the plurality of work function adjustment patterns 132, and the plurality of second contact pads 122 are formed.

The contact holes 111CH of the interlayer insulating layer 111 may be formed, and then, the plurality of first contact pads 121 may be formed to partially fill the contact holes 111CH through a CVD process. Subsequently, the plurality of work function adjustment patterns 132 may be formed to partially fill the contact holes 111CH through the CVD process. Subsequently, the plurality of second contact pads 122 may be formed to respectively fill the remaining contact holes 111CH through a CVD process.

P120 to P150 are substantially the same as those described with reference to FIGS. 8 to 9D, and thus, redundant descriptions thereof will be omitted.

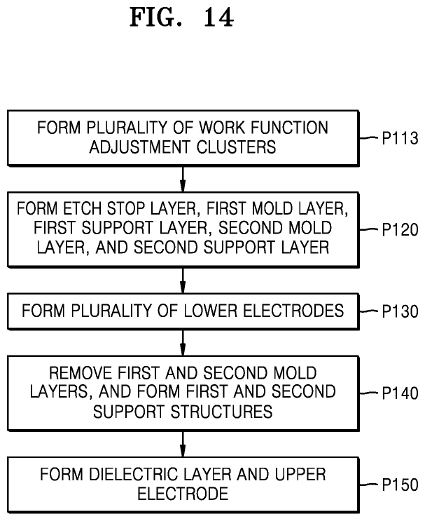

FIG. 14 is a flowchart illustrating a method of manufacturing a semiconductor memory device according to some embodiments.

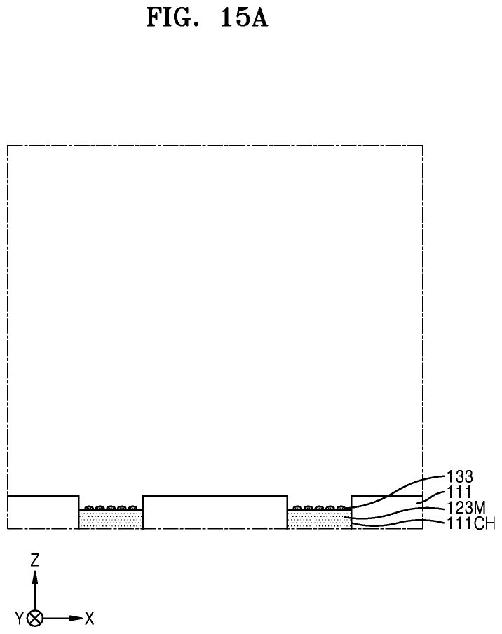

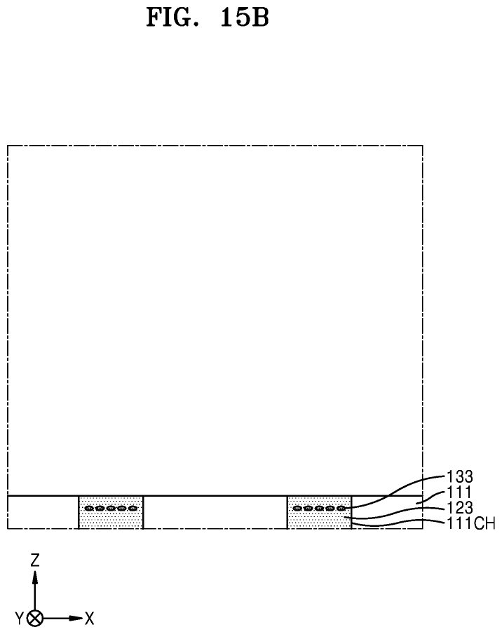

FIGS. 15A and 15B are cross-sectional views illustrating the method of manufacturing the semiconductor memory device according to some embodiments.

Referring to FIGS. 14 to 15B, in P113, the plurality of work function adjustment clusters 133 are formed.

The contact holes 111CH of the interlayer insulating layer 111 may be formed, and then a contact pad material 123M may be formed to partially fill the contact holes 111CH through a CVD process. Subsequently, the plurality of work function clusters 133 may be formed on the contact pad material 123M through the CVD process. According to some embodiments, the plurality of work function clusters 133 may be formed, by performing a CVD process for a time shorter than the minimum time necessary for forming a continuous film. Then, the plurality of contact pads 123 may be formed, by filling the remaining contact holes 111CH with a conductive material, such as tungsten through the CVD process.

P120 to P150 are substantially the same as those described with reference to FIGS. 8 to 9D, and thus redundant descriptions thereof will be omitted.

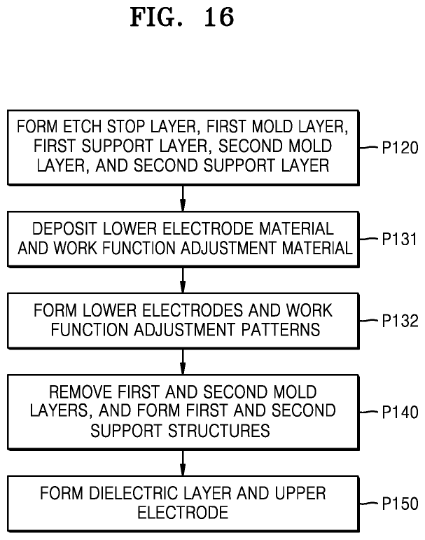

FIG. 16 is a flowchart illustrating a method of manufacturing a semiconductor memory device according to some embodiments.

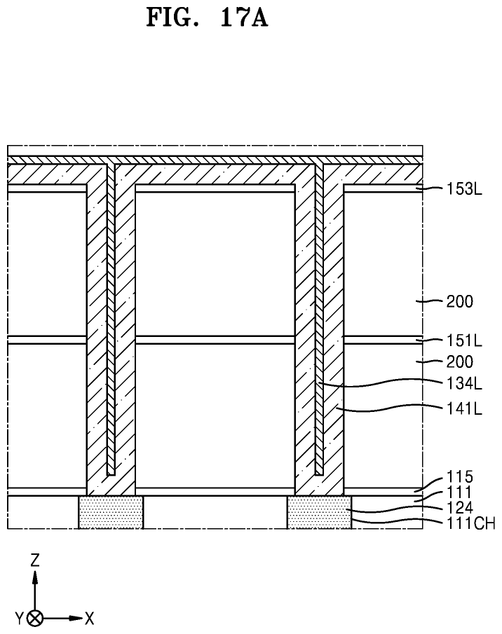

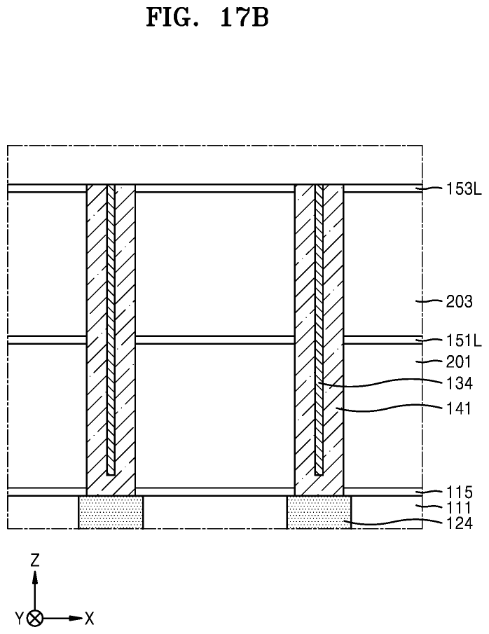

FIGS. 17A and 17B are cross-sectional views illustrating the method of manufacturing the semiconductor memory device according to some embodiments.

In the present embodiment, the contact holes 111CH are filled by the contact pads 124 including, for example, a conductive material, such as tungsten, and thus P110 of FIG. 8 may be omitted. P120, P140, and P150 are substantially the same as those described with reference to FIGS. 8 to 9D, and thus redundant descriptions thereof will be omitted.

Referring to FIGS. 16 and 17A, in P131, a lower electrode material 141L and a work function adjustment material 134L are deposited.

According to some embodiments, the lower electrode material 141L and the work function adjustment material 134L may be formed by ALD. Accordingly, the lower electrode material 141L may have a uniform thickness, and may have a conformal structure. The work function adjustment material 134L may be provided to sufficiently fill an opening defined by the lower electrode material 141L.

Subsequently, referring to FIGS. 16 to 17B, in P132, the lower electrodes 141 and the work function adjustment patterns 134 may be formed.

According to some embodiments, the plurality of lower electrodes 140 and the plurality of work function adjustment patterns 134 may be formed, by removing upper portions of the lower electrode material 141L and the work function adjustment material 134L using CMP having the upper surface of the second support layer 153L as an endpoint.

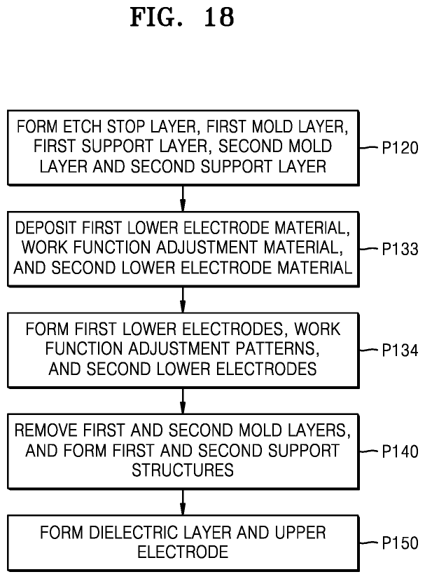

FIG. 18 is a flowchart illustrating a method of manufacturing a semiconductor memory device according to some embodiments.

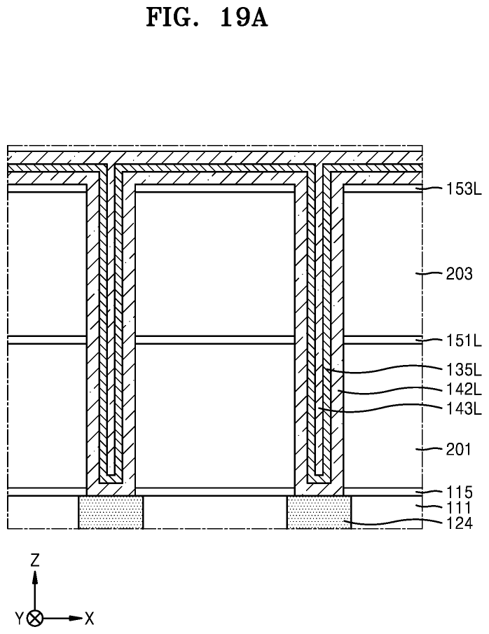

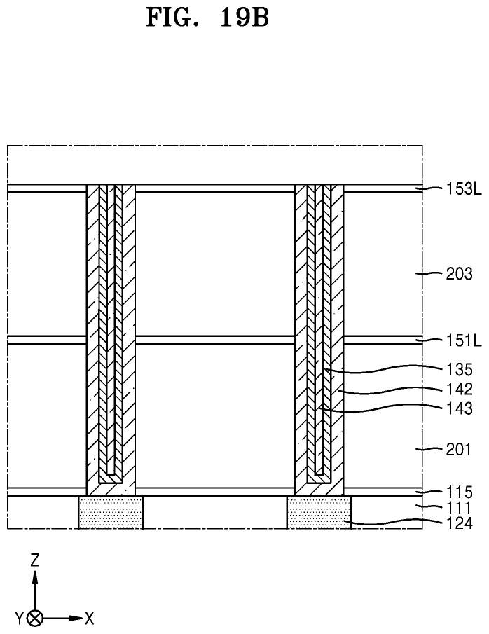

FIGS. 19A and 19B are cross-sectional views illustrating the method of manufacturing the semiconductor memory device according to some embodiments.

P120, P140, and P150 are substantially the same as those described with reference to FIGS. 8 to 9D, and thus redundant descriptions thereof will be omitted.

Referring to FIGS. 18 and 19A, in P133, a first lower electrode material 142L, a work function adjustment material 135L, and a second lower electrode material 143L are deposited.

According to some embodiments, the first lower electrode material 142L, the work function adjustment material 135L, and the second lower electrode material 143L may be formed by ALD. Accordingly, the first lower electrode material 142L and the work function adjustment material 135L may have a uniform thickness, and may have a conformal structure. The second lower electrode material 143L may be provided to sufficiently fill an opening defined by the work function adjustment material 134L.

Subsequently, referring to FIGS. 18 to 19B, in P134, the first lower electrodes 142, the work function adjustment patterns 135, and the second lower electrodes 143 may be formed.

According to some embodiments, the first lower electrodes 142, the work function adjustment patterns 135, and the second lower electrodes 143 may be formed, by removing upper portions of the first lower electrode material 142L, the work function adjustment material 135L, and the second lower electrode material 143L using CMP having an upper surface of the second support layer 153L as an endpoint.

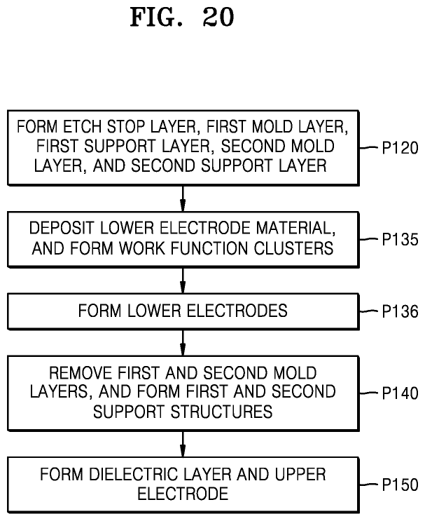

FIG. 20 is a flowchart illustrating a method of manufacturing a semiconductor memory device according to some embodiments.

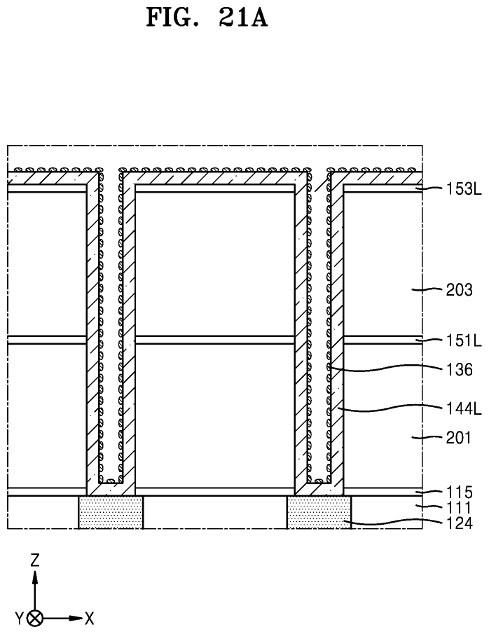

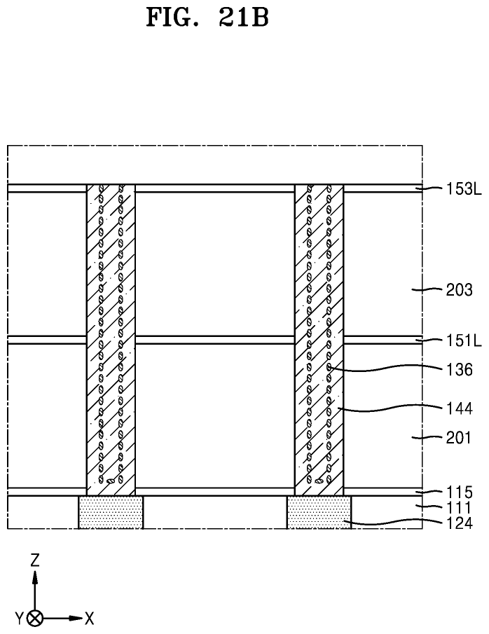

FIGS. 21A and 21B are cross-sectional views illustrating the method of manufacturing the semiconductor memory device according to some embodiments.

P120, P140, and P150 are substantially the same as those described with reference to FIGS. 8 to 9D, and thus redundant descriptions thereof will be omitted.

Referring to FIGS. 20 and 21A, in P135, a lower electrode material 144L is deposited, and work function clusters are formed.

The lower electrode material 144L may be formed by ALD. Accordingly, the first lower electrode material 144L may have a uniform thickness, and may have a conformal structure.

According to some embodiments, the plurality of work function clusters 136 may be formed by performing an ALD process for a time shorter than the minimum time necessary for forming a continuous film.

Then, referring to FIGS. 20 to 21B, in P136, the lower electrodes 144 are formed.

A lower electrode material may be further provided to fill space defined by the lower electrode material 144L through the ALD process and to cover the plurality of work function clusters 136. Next, the lower electrodes 144 may be formed, by removing an upper portion of the lower electrode material 144L and the plurality of work function clusters 136 using CMP having an upper surface of the second support layer 153L as an endpoint.

It will be understood that, although the terms first, second, third etc. may be used herein to describe various elements, components, regions, layers, directions, and/or sections, these elements, components, regions, layers, directions, and/or sections should not be limited by these terms. Unless the context indicates otherwise, these terms are only used to distinguish one element, component, region, layer, direction, or section from another element, component, region, layer, direction, or section, for example as a naming convention. Thus, a first element, component, region, layer, direction, or section discussed below in one section of the specification could be termed a second element, component, region, layer, direction, or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

While the inventive concept has been particularly shown and described with reference to embodiments thereof, it will be understood that various changes in form and details may be made therein without departing from the spirit and scope of the following claims.

1. A semiconductor memory device comprising:
a substrate;
an interlayer insulating layer formed on the substrate;
a plurality of first contact pads embedded in the interlayer insulating layer;
a plurality of first work function adjustment patterns embedded in the interlayer insulating layer and respectively disposed on the plurality of first contact pads, the plurality of first work function adjustment patterns configured to adjust a work function of structures that include the plurality of first contact pads;
a plurality of lower electrodes respectively disposed on the plurality of first work function adjustment patterns;
an upper electrode covering the plurality of lower electrodes; and
a dielectric layer disposed between the upper electrode and the plurality of lower electrodes.

2. The semiconductor memory device of claim 1, wherein each work function adjustment pattern of the plurality of first work function adjustment patterns comprises a metal chalcogenide.

3. The semiconductor memory device of claim 1, wherein each work function adjustment pattern of the plurality of first work function adjustment patterns comprises any one of WS₂, MoS₂, WSe₂, MoSe₂, MoS₂, TaTe₂, VTe₂, NbTe₂, TaSe₂, VSe₂, NbSe₂, TaS₂, VS₂, NbS₂, VSe₂, TaS₂, TiTe₂, TiSe₂, TiS₂, and graphene doped with an N-type dopant.

4. The semiconductor memory device of claim 1, wherein a work function of a material included in the plurality of first work function adjustment patterns is greater than a work function of a material included in the plurality of first contact pads.

5. The semiconductor memory device of claim 1, wherein:
the plurality of first contact pads comprise tungsten, and
each of the plurality of first work function adjustment patterns comprises a material having a work function equal to or greater than 4.6 eV.

6. The semiconductor memory device of claim 1, wherein a thickness of each of the plurality of first work function adjustment patterns is in a range of about 1 nm to about 10 nm.

7. The semiconductor memory device of claim 1, further comprising a plurality of second contact pads respectively disposed on the plurality of first work function adjustment patterns,
wherein the plurality of second contact pads comprise the same material as a material of the plurality of first contact pads.

8. The semiconductor memory device of claim 1, further comprising a plurality of second work function adjustment patterns respectively disposed on the plurality of first work function adjustment patterns,
wherein the plurality of second work function adjustment patterns comprise a material different from a material of the plurality of first work function adjustment patterns.

9. The semiconductor memory device of claim 8,
wherein the plurality of first contact pads comprise tungsten, and
each of the plurality of first and second work function adjustment patterns comprises a material having a work function equal to or greater than 4.6 eV.

10. The semiconductor memory device of claim 8, wherein a sum of a thickness of each of the plurality of first work function adjustment patterns and a thickness of a corresponding second work function adjustment pattern is a thickness in a range of about 1 nm to about 10 nm.

11. The semiconductor memory device of claim 1, wherein the plurality of lower electrodes extend in a first direction perpendicular to a top surface of the substrate.

12. The semiconductor memory device of claim 11, wherein the plurality of lower electrodes and the upper electrode form a plurality of capacitors.

13. The semiconductor memory device of claim 11, wherein top surfaces of the plurality of first work function adjustment patterns are at or below a bottom-most surface of the plurality of lower electrodes.

14. A semiconductor memory device comprising:
a substrate;
an interlayer insulating layer formed on the substrate;
a plurality of contact pads embedded in the interlayer insulating layer;
a plurality of first lower electrodes respectively disposed on the plurality of contact pads and extending in a first direction perpendicular to a top surface of the substrate;
a plurality of work function adjustment patterns respectively embedded in the plurality of first lower electrodes;
an upper electrode covering the plurality of first lower electrodes; and
a dielectric layer disposed between the upper electrode and the plurality of first lower electrodes.

15. The semiconductor memory device of claim 14, wherein each of the plurality of work function adjustment patterns comprises any one of WS₂, MoS₂, WSe₂, MoSe₂, MoS₂, TaTe₂, VTe₂, NbTe₂, TaSe₂, VSe₂, NbSe₂, TaS₂, VS₂, NbS₂, VSe₂, TaS₂, TiTe₂, TiSe₂, TiS₂, and graphene doped with a N-type dopant.

16. The semiconductor memory device of claim 14, wherein each of the plurality of work function adjustment patterns has a bar shape.

17. The semiconductor memory device of claim 14, wherein each of the plurality of work function adjustment patterns has a cup shape.

18. The semiconductor memory device of claim 17, further comprising a plurality of second lower electrodes embedded respectively in the plurality of work function adjustment patterns and comprising the same material as a material of the plurality of first lower electrodes.

19. The semiconductor memory device of claim 14, wherein:
a cross-section of each of the plurality of work function adjustment patterns has a ring shape, and
a difference between an inner radius and an outer radius of the ring shape is in a range of about 1 nm to about 10 nm.

20. The semiconductor memory device of claim 14, wherein the plurality of first lower electrodes and the upper electrode form a plurality of capacitors.

21-24. (canceled)
